(19) United States
(12) Patent Application Publication
(10) Pub. No.: US 2002/0166838 A1
(43) Pub. Date: Nov. 14, 2002

(54) Sloped trench etching process

(75) Inventor: Ranganathan Nagarajan, Singapore (SG)

Correspondence Address: Steven R. Greenfield, JENKENS & GILCHRIST, P.C., 3200 Fountain Place, 1445 Ross Avenue, Dallas, TX, 75202-2799, US

(73) Assignee: Institute of Microelectronics

(21) Appl. No.: 09/900,293

(22) Filed: Jul. 6, 2001

(30) Foreign Application Priority Data
May 10, 2001 (SG) 200102727-5

(51) Int. Cl. H01L 21/302

(52) U.S. Cl. 216/2; 216/49; 216/67; 216/79; 438/43; 438/701; 438/719; 438/733; 438/734; 438/946; 438/978

(57) ABSTRACT

Method and apparatus for etching a tapered trench in a layer of material with a highly controllable wall profile. The layer of material has a mask adjacent a surface thereof having an opening which defines a location on the layer of material at which the trench is to be formed. Vertical etch process steps and opening enlarging process steps are then performed in an alternating manner until the trench has been etched to a desired depth. The method permits very deep tapered trenches of up to 80-100 um or more to be formed in a silicon substrate or other layer of material in a highly controllable manner. The method can be incorporated into processes for manufacturing numerous devices including MEMS devices and high power RF devices such as LDMOS and VDMOS devices.

### BACKGROUND OF THE INVENTION

1. Field of the Invention

The present invention relates generally to etching processes; and, more particularly, to a method and apparatus for etching tapered trenches in a layer of material with a controlled wall profile.

2. Description of the Prior Art

The etching of trenches in a semiconductor substrate is an important part of the overall process of manufacturing many integrated circuit devices. The fabrication of such trenches, however, presents a number of difficulties which are not suitably addressed by many existing processes. For example, some of the more important problems that are associated with current trench etching processes include the following:

Inadequate Trench Sidewall Profile Control

The trench sidewall profile is of particular concern in many applications. For example, trench profiles where the substrate is undercut with respect to a patterning mask or where “cusping” is exhibited under the mask is highly undesirable. Even minutely undercut sidewall profiles will readily promote void formation during subsequent CVD refill operations commonly used in typical device processing. In applications where a tapered trench profile is desired for better metal interconnect step-coverage, the slope of the trench becomes even more critical.

Very Low Etch Rate

In general, for a manufacturing process to be practical, it should provide a reasonable throughput. With respect to a trench etching process, in particular, it is important that the process provide a good trench etch rate (e.g., >1 um/min). In known etching processes of sloping an underlying film by etching resist and film at the same time, the etch gases become loaded by both resist and the film to be etched. This greatly reduces the etch rate. Also, very deep trenches cannot be etched utilizing these processes without overheating the resist. This causes further resist flow which, in turn, results in a loss of etch profile control

Low Trench Depth and Lack of Profile Control for Deep Trenches

Existing etch processes are typically effective in etching sloped trenches to depths of up to only about 10 um. Many semiconductor integrated circuits currently being fabricated, however, require trenches having depths of, for example, 80-100 um. In Micro Electro Mechanical Systems (MEMS) and RF power semiconductor processes, such as LDMOS and VDMOS, for example; many new devices are emerging which have 3-dimensional structures which make use of very deep silicon trench etch processes. There is a substantial need for integrating these processes with backend metallization and interconnect processes with good trench-fill and step coverage. When such trenches are formed prior to metallization to provide electrical contacts to underlying regions, it is preferable that they have a sloped profile so as to minimize the possibility of step-coverage induced defects in the metal layer. Existing deep trench etching processes, however, provide sidewalls which are vertical or very nearly vertical, and this makes it difficult to carry out subsequent etch processing as the steep wall profile gives rise to stingers.

Lack of Suitable and Controllable Etch Chemistry

The etch process chemistry should offer a robust process with controllable process parameters. As the resist and silicon are etched at the same time, it is difficult to control one without affecting the other. For this kind of process, the favored gas mixture is fluorocarbon/oxygen which generates a large amount of polymer. This reduces the etch rate as the polymer has to be constantly cleared during the etching process.

One known technique for providing a sloped sidewall profile during anisotropic plasma or reactive ion etching is to vary the ion bombardment energy. This technique, however, requires a complex triode or a flexible diode reactor; and it is often difficult to precisely control the profile. The prior art discloses various methods for tailoring the reactive etchant species used in plasma etching to achieve a particular etch rate and selectivity relative to the layer being etched, the underlying layer and the photoresist mask layer. For example, U.S. Pat. No. 4,174,251 to Paschke describes a two-step etching process for a low pressure plasma reactor wherein a silicon nitride layer is etched through a hydrocarbon photoresist mask without destroying the mask layer. The process includes a pre-etch step using a high plasma power level and a 95:5 CF₄:O₂ etchant gas to etch halfway through the silicon nitride layer, followed by a main etch step at a lower power level, using a 50:50 CF₄:O₂ etchant gas to etch the remainder of the silicon nitride layer

U.S. Pat. No. 3,940,506 to Heinecke discloses a method of adjusting the concentration of a reducing species, such as hydrogen, in aplasmato control the relative etch rates of silicon and silicon dioxide or silicon nitride, particularly for use in a low pressure plasma reactor. Hydrogen is used to control the selectivity and may be added to the CF₄ etchant gas mixture by using a partially fluorine substituted hydrocarbon such as CHF₃.

U.S. Pat. No. 4,324,611 to Vogel, et al. describes a method for tailoring a reagent gas mixture to achieve a high etch rate, high selectivity and low breakdown of photoresist in a single wafer, high power, high pressure reactor. The disclosed reagent gas mixture includes a primary etching gas consisting of a pure carbon-fluorine, and a secondary gas containing hydrogen to control the selectivity of the etch. A tertiary gas containing helium maybe included to prevent the breakdown of the photoresist mask layer. In one embodiment for plasma etching silicon dioxide or silicon nitride overlying silicon, the primary gas is C₂F₆ and the secondary gas is CHF₃.

U.S. Pat. No. 4,855,017 to Douglas describes a plasma dry etch process for trench etching in single slice RIE etch reactors wherein a selective sidewall passivation is accomplished to control the profile of the trench being etched. The process comprises methods of passivating the sidewall by passivation on a molecular scale and by a veneer-type passivation comprising buildup of a macroscopic residue over the surface of the sidewall. Several methods are disclosed for forming and shaping the passivating layers (both mono-atomic and bulk). By carefully controlling the composition and shape of the sidewall passivating veneer in conjunction with other etch factors, desired trench profiles can be achieved.

In general, many prior techniques focus on developing processes that can give a sloped etch profile in silicon by manipulating the insitu sidewall passivation or by using external sidewall passivation deposition processes.

U.S. Pat. No. 4,690,729 to Douglas describes a plasma dry etch process for etching deep trenches in a single crystal silicon material with controlled wall profile, for trench capacitors in trench isolation structures. HCl is used as an etchant under RIE conditions with a SiO₂ hard mask. The SiO₂ hard mask is forward sputtered during the course of the Si etch so as to slowly deposit SiOₓ (x<2) on the sidewalls of the silicon trench. Since the sidewall deposit shadows etching at the bottom of the trench near the sidewall, the effect of this gradual buildup is to produce a positively sloped trench sidewall without “grooving” the bottom of the trench, and without line width loss. This process avoids prior art problems of mask undercut, which generates voids during subsequent refill processing, and grooving at the bottom of the trench, which is exceedingly deleterious to thin capacitor dielectric integrity.

Apart from the above-described prior art, which deal with dry etch chemistries, there are numerous arts which deal with wet chemistries using KOH, TMAH, etc. These techniques are broadly called orientation dependent etch. Hence, the etch profile cannot be changed within the wafer as the orientation is fixed. These methods also cannot be used for small openings with a requirement to etch deep trenches.

In general, processes such as described above may be suitable for etching sloped trenches having a depth of up to about 10 um. However, as also indicated above, for high power RF devices such as LDMOS/VDMOS devices and MEMS devices, there is an important need to work with much deeper and more tapered trenches. There is no dry etch process available, however, that is able to etch deep tapered trenches to depths in the range of 10-100 um. Furthermore, as mentioned above, even when only relatively shallow trench depths are required for particular applications, existing processes are not fully satisfactory in any event inasmuch as they suffer from various inadequacies including the lack of good control over the slope of the trench, the use of hazardous gases and the need for frequent maintenance of the process chamber.

### SUMMARY OF THE INVENTION

The present invention provides a method and apparatus for etching a tapered trench in a layer of material, such as a silicon substrate, with a highly controllable wall profile.

More particularly, the present invention provides a method for etching a tapered trench in a layer of material which has a mask adjacent a surface thereof, the mask having an opening which defines a location on the layer of material at which the trench is to be formed. A method, according to the invention, may comprise steps of performing a vertical etch process step on the layer of material, enlarging the opening in the mask, and repeating the vertical etch process step and the mask opening enlarging step in an alternating manner until a trench has been etched to a desired depth.

With the present invention, a tapered trench can be formed in a layer of material, such as a silicon substrate, to a desired depth; while, at the same time, maintaining excellent control over the wall profile of the trench. In addition, with the method of the present invention, tapered trenches having substantially any desired depth, including relatively shallow trenches having a depth of, for example, about 10 um or less, up to very deep trenches having a depth of, for example, about 80-100 um or more, can readily be fabricated. Although it is not intended to limit the invention to any particular application, the present invention is especially suitable for use in applications such as the manufacture of MEMS and high power RF devices which often require very deep trenches in order to form numerous types of 3-dimensional structures that have been developed.

In accordance with a presently preferred embodiment of the invention, the mask comprises a resist mask, and the step of enlarging the opening in the mask comprises performing a resist etch process step to enlarge the opening. A vertical etch process step is performed following each resist etch process step to gradually build the trench as a series of trench portions which gradually decrease in size as the trench extends from the surface into the layer of material so as to define the tapered profile of the trench. By controlling the depth of the etch during each vertical etch process step, and the extent to which the opening is enlarged by each resist etch process step, the slope of the trench can be precisely controlled.

According to a presently most preferred embodiment of the invention, the initial profile of the resist mask around the periphery of the opening is suitably rounded, for example, by baking at a high temperature, so that the thickness of the resist mask will be tapered at the resist/layer of material interface. This facilitates the enlarging of the resist mask opening following each vertical etch process step and permits the amount by which the trench opening is enlarged by each resist etch process step to be conveniently built into the mask design so that there will be no unforseen loss of critical dimension.

The method according to the present invention can be designed as either a multi-step etch process or as a pulsed etch process, depending on the etch tool used. For example, an ICP RIE tool with the capability of performing a cyclical etch process (i.e., cycling or repeating the vertical etch process step and the resist etch process step a specified number of times) can conveniently be used in practicing the method of the present invention. The etching method according to the invention allows etch parameters to be independently controlled by specifying the pressure, power, gas flows, time duration of the process and the number of cycles to be run.

In general, the present invention provides a method and apparatus for controllably etching tapered trenches, including very deep tapered trenches, in a substrate or other layer of material that utilizes only harmless gases and that avoids use of chemistry that poses a risk of corrosion to aluminum interconnects. The method does not generate any polymeric materials that must be cleaned from the chamber and also does not require the use of a dielectric mask layer as in many prior techniques.

Yet further advantages and specific features of the present invention will become apparent hereinafter in conjunction with the following detailed description of presently preferred embodiments of the invention.

### BRIEF DESCRIPTION OF THE DRAWINGS

FIGS. 1-7 schematically illustrate steps of a sloped trench etching process according to a presently preferred embodiment of the invention;

FIG. 8 is a flow chart summarizing the steps of the trench etching process illustrated in FIGS. 1-7; and

FIGS. 9a-9c, 10a-10c, 11a-11b and 12a-12b schematically illustrate steps of a method for fabricating a Z-axis accelerometer according to an embodiment of the present invention.

### DETAILED DESCRIPTION OF PRESENTLY PREFERRED EMBODIMENTS

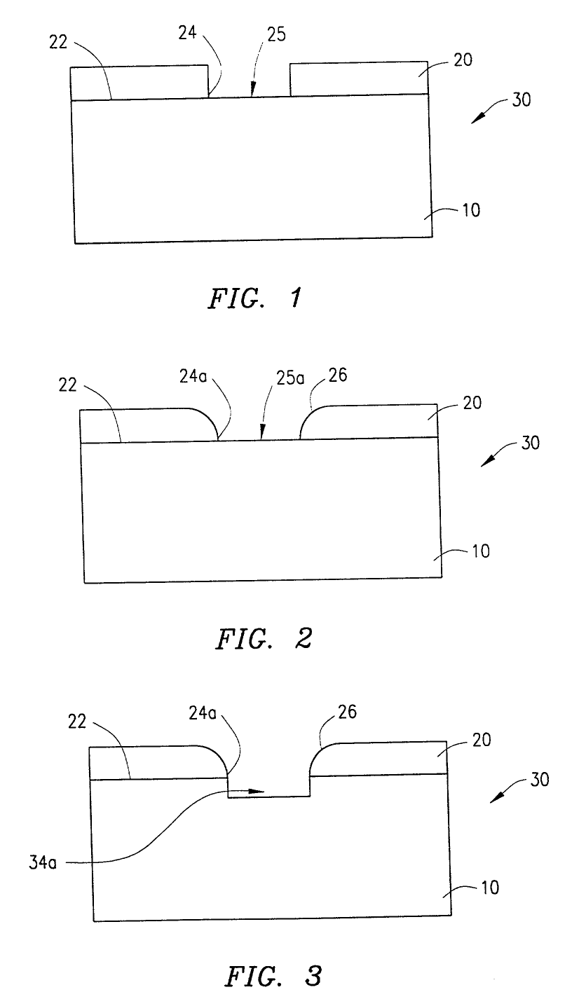

FIGS. 1-7 schematically illustrate steps of a sloped trench etching process according to a presently preferred embodiment of the invention, and FIG. 8 is a flow chart which summarizes steps of the process.

FIG. 1 illustrates a semiconductor substrate, for example, a silicon substrate, in which a trench is to be formed. The substrate is generally designated by reference number 10; and, as shown in FIG. 1, is initially provided with a mask member in the form of a resist layer 20 on upper surface 22 thereof from which the trench is to extend into the substrate. The substrate 10 having the resist layer 20 thereon is sometimes generally referred to herein as a wafer 30. As also shown in FIG. 1, the resist layer 20 includes a suitably formed and located opening 24 therein which defines an exposed area or region 25 on the surface 22 of the substrate 10 at which the trench is to be formed.

Although it is not essential to the practice of the method of the present invention, it is preferred that the profile of the resist layer 20 around the periphery of opening 24 be suitably rounded as illustrated at 26 in FIG. 2 (step 50 in FIG. 8) so that the thickness of the resist layer will be tapered at the resist-substrate interface. This is preferably accomplished by hard baking the wafer at a high temperature of, for example, >145° C., for a short period of time so that the resist layer will flow somewhat around the opening creating the rounded structure indicated at 26. As will become apparent hereinafter, tapering the resist layer around the opening (in FIG. 2, the opening is designated by reference number 24a, and defines exposed region 25a on surface 22) facilitates enlarging the opening during subsequent steps of the trench etching process.

A first vertical etch process step is then performed using an etch process having a high selectivity to the resist layer to create a shallow trench structure comprised of trench portion 34a which extends into the substrate 10 from surface 22 as illustrated in FIG. 3 (step 60 in FIG. 8). Trench portion 34a has lateral dimensions which are defined by the size and shape of the mask opening 24a, and has vertically oriented sidewalls. The depth of portion 34a is a function of various parameters of the overall vertical etch process step as is well-known to those skilled in the art including the pressure, power, gas flows and time duration of the step. As will be discussed more fully hereinafter, an important aspect of the present invention is that each of these various parameters can be independently controlled so as to provide substantial control of the overall trench forming process.

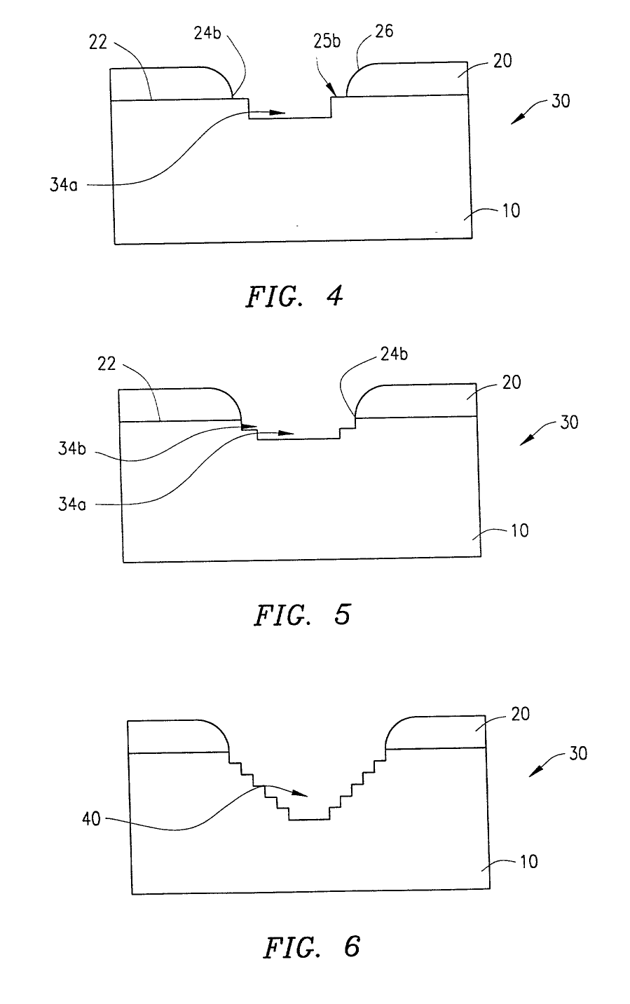

Following the first vertical etch process step, a first resist etch process step is performed to enlarge the size of the opening 24a defined by the resist layer (the enlarged opening is designated by reference number 24b in FIG. 4) so as to expose a slightly larger region 25b of the substrate surface (step 70 in FIG. 8). Because, as was mentioned above, the resist layer 20 is tapered around the opening, the amount by which the opening is enlarged by the resist etch process step is, in effect, built into the design of the resist layer; and, thus, can be quite easily controlled so as to reduce the risk of unforseen loss of critical dimension. Also, since the resist layer is quite thin in the vicinity just around the opening, the enlarging step can be accomplished in a relatively short period of time.

Following the first resist etch process step, a second vertical etch process step is performed. As illustrated in FIG. 5, this step extends the depth of trench portion 34a (without changing its lateral dimensions); and, at the same time, creates a second trench portion 34b having vertical sidewalls and lateral dimensions which are defined by the enlarged opening 24b in the resist layer. As should be apparent from FIG. 5, the result of the second vertical etch process step is to form an overall trench structure having a generally stepped or staircase-like configuration.

Following the second vertical etch process step, a second resist etch process step is performed to further enlarge the opening 24 in the resist layer; and, thereafter, vertical etch process steps and resist etch process steps are performed in an alternating manner. As the steps are performed, the depth of the trench is gradually increased; and, at the same time, the lateral dimensions of the trench are caused to gradually increase in a step-wise fashion from the bottom to the top of the trench. The vertical etch process step and the resist etch process step are continued in an alternating manner, as shown by the NO output of question block 80 in FIG. 8, until the trench has been formed to the desired depth, as indicated by the YES output of question block 80 in FIG. 8. A completed trench 40 formed to a desired depth from a large number of trench portions is illustrated in FIG. 6.

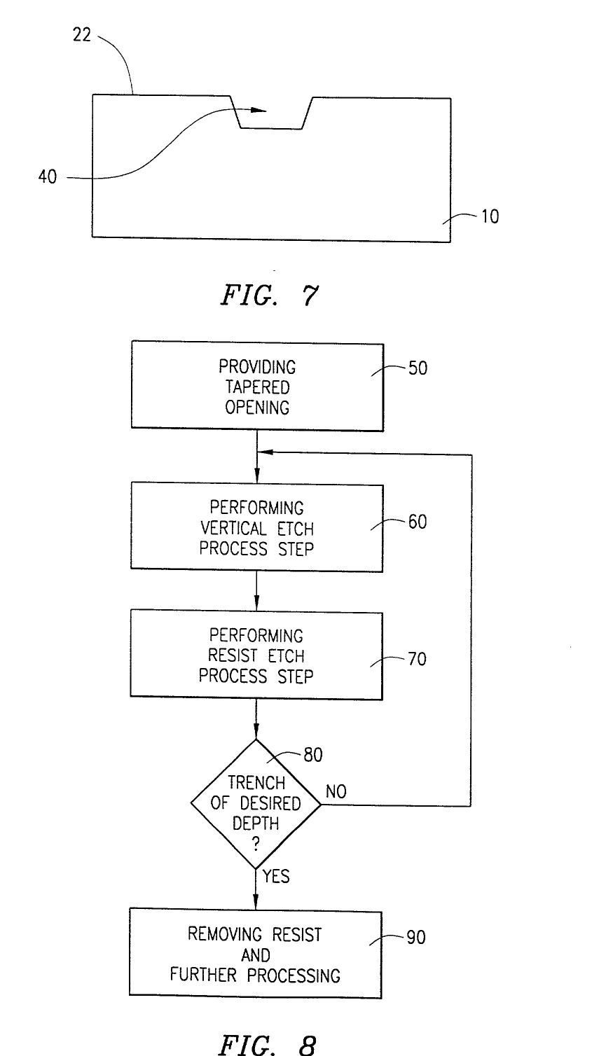

After the trench has been formed to the desired depth, the remaining resist layer is removed from the substrate 10 as shown in FIG. 7, and subsequent processing may then be performed depending on the particular application for which the trench has been fabricated (step 90 in FIG. 8). FIG. 7 also emphasizes that in a typical application of the method of the present invention, the trench 40 is formed in a large number of steps and comprises a large number of trench portions such that each individual portion is quite small, and the sidewalls of the completed trench will, in effect, function as substantially smooth surfaces.

With the present invention, trenches can be formed in a substrate having substantially any desired depth from, for example, rather shallow trenches of up to about 10 um deep to very deep trenches of about 80-100 um deep or more. The trenches can also be formed to have substantially any desired slope, for example, from about 45 degrees to about 80 degrees; while, at the same time, maintaining excellent control over the sidewall profile. By way of example, trenches having a depth of about 80 um and a slope of about 80 degrees have been accurately formed in silicon substrates using the method of the present invention.

The method according to the present invention can be performed as a multi-step process or as a pulsed etch process depending on the type of etching tool used. The applicant has, for example, effectively used an ICP RIE tool with the capability of performing a cyclical etch process. It should be recognized, however, that it is not intended to limit the invention to the use of any particular type of tool or tools, or to limit the invention to any particular vertical etch process or resist etch process.

As one example of an application of the present invention, a tapered trench having a depth of 80 um and sidewalls sloped at 80 degrees can be fabricated by building up the trench with approximately 150-160 or more trench segments. Each trench segment can be formed to have a depth of about 0.4-0.5 um during each vertical etch process step; and by enlarging the opening in the resist layer by about 0.1-0.2 um during each resist etch process step. The process can be efficiently carried out using an ICP RIE tool or another suitable tool in a time period of, for example, 80-100 minutes. In general, the process can be implemented with any etch tool that has the capability to run two etch processes alternately such as an STS multiplex ICP etch system. It should also be understood that the above is intended to be one example only of an application of the present invention, as the invention may be varied significantly depending on the type of tool used and on many other factors.

The tapered trench fabrication process according to the present invention can readily be integrated into overall procedures typically performed in the manufacture of semiconductor integrated circuits, MEMS devices, RF power semiconductor devices and the like. For example, the trench etching process of the present invention can be followed up by any suitable metal deposition procedures. Due to the slope of the trench, the deposition is very conformal in nature; and the procedure has been successfully used in applications which use 3-dimensional device structures with final metal interconnect.

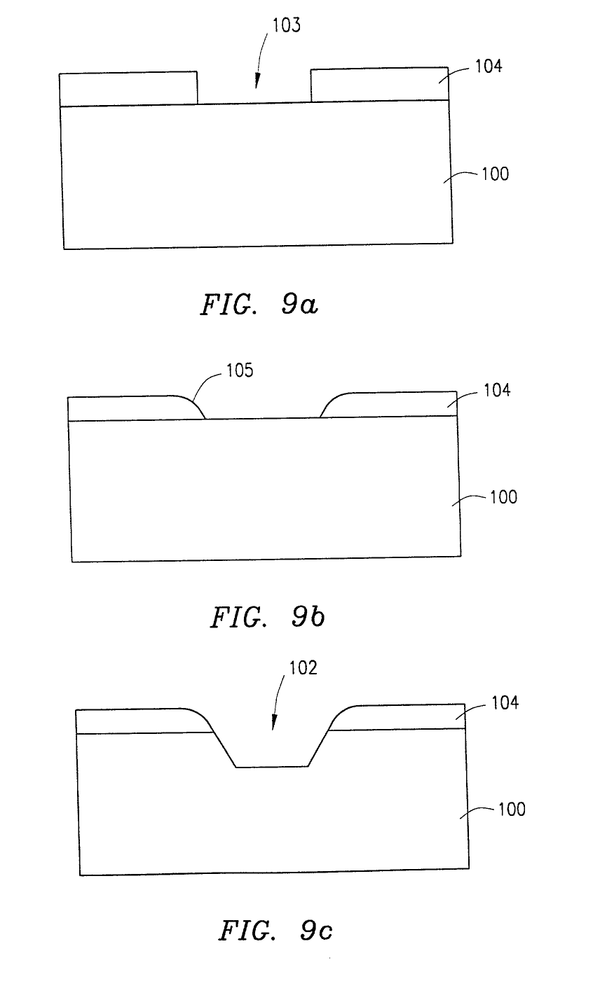

To emphasize the wide applicability of the present invention, FIGS. 9-12 schematically illustrate steps for fabricating a Z-axis accelerometer according to one presently preferred embodiment of the invention.

Conventional accelerometers have silicon beams on the same plane. Hence, they are able to sense movement only in the x-axis or the y-axis. In order to also sense movement in the z-axis, it is necessary to make beams which are positioned in two planes. This can readily be accomplished using the sloped trench etching process of the present invention.

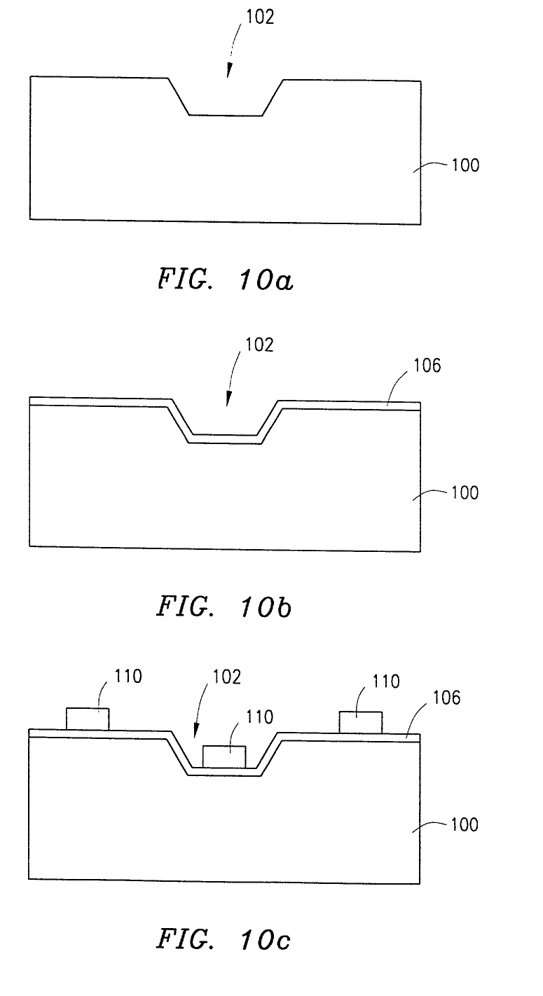

Initially, as shown in FIGS. 9a-9c, the cavity for the z-axis is defined. Specifically, a substrate 100 is provided with a resist layer 104 within which a suitably formed and located opening 103 has been provided (FIG. 9a); and then the resist layer is rounded around the opening as shown at 105 in FIG. 9b. A tapered cavity 102 is then etched in the silicon substrate 100 as shown in FIG. 9c utilizing the trench etching process described above with reference to FIGS. 1-8. Thereafter, as shown in FIGS. 10a-10c, the remaining resist layer 104 is removed (FIG. 10a), a masking oxide deposition procedure is performed to apply an oxide layer 106 onto the exposed surfaces of the substrate (FIG. 10b), and a sensor masking and cavity oxide etch procedure is carried out to define the masks 110 for the sensor beams (FIG. 10c).

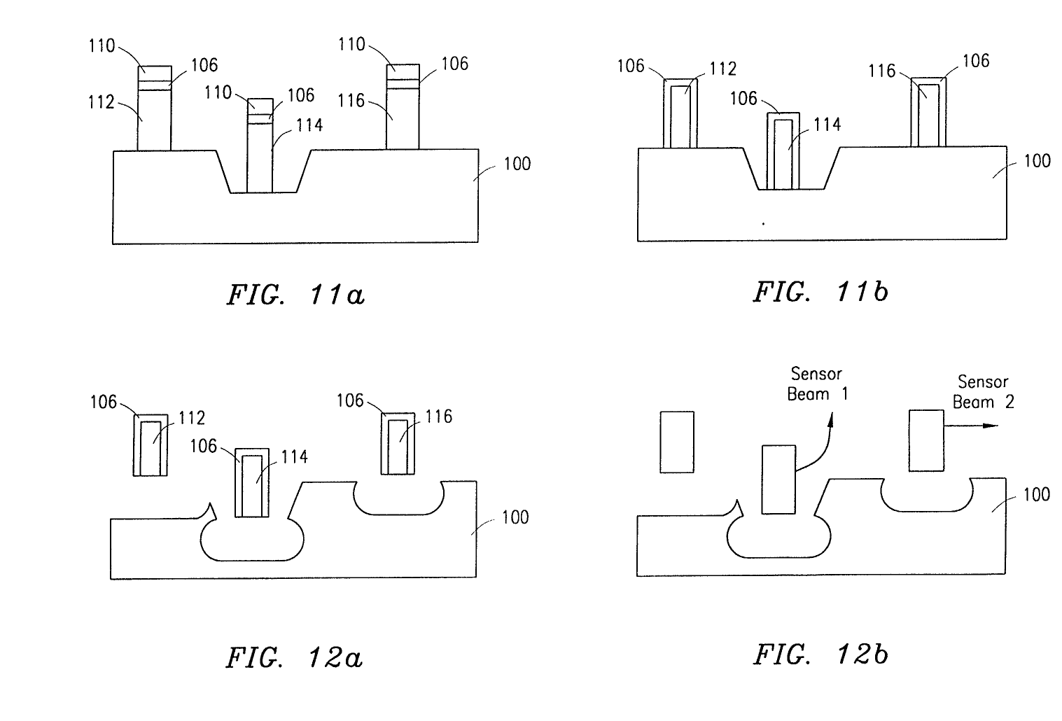

Thereafter, silicon trenches are etched as shown in FIG. 11a. These trenches are formed in different planes. Subsequently, a layer of oxide is deposited and etched back using an RIE process. This forms oxide spacers by the side of the silicon beams 112, 114 and 116 as shown in FIG. 11b. Then silicon beams 112 and 114 are undercut and release etched (FIG. 12a) to form a sensor beam 1 and sensor beam 2 at two planes. Finally, the spacer oxide is stripped along with the masking oxide (FIG. 12c).

The tapered trench etching method according to the present invention can be advantageously incorporated into processes for the fabrication of numerous structures including MEMS devices and RF power semiconductor devices such as LDMOS and VDMOS devices. By utilizing the method according to the present invention to fabricate a trench LDMOS, for example, a reduction of P+sinker resistance between the source and the substrate is achieved with a reduction of 7-8 hours in implant drive-in time.

In general, the tapered trench fabricating method according to the present invention provides a number of significant advantages over existing fabricating procedures. Among such advantages include the following:

1. As mentioned previously, the method according to the present invention can be used to etch very deep sloped trenches (up to a depth of 80-100 um or more); while, at the same time, the method is just as effective in etching shallower trenches (about 10 um or less). Existing procedures, on the other hand, are generally effective in forming sloped trenches up to a depth of only about 10 um.

2. In many prior techniques, particularly in earlier techniques, trench etching in silicon is done using a combination of HCl, HBr, SiCl₄ and BCl₃ which are not only hazardous in nature, but also react with the process chamber walls and rapidly reduce their useful life. They also produce by-products that redeposit themselves on the chamber walls and, hence, necessitate frequent maintenance. The process according to the present invention can be carried out using only harmless gases such as SF₆ and O₂ which produce by-products which are highly volatile and thus necessitate very little maintenance.

3. The prior art frequently uses chlorine or bromine chemistry to etch silicon trenches. The use of these materials imposes an additional post-etch cleaning process to clear the by-products from the wafer to avoid corrosion with aluminum interconnects. In practicing the present invention, a process such as a SF₆/C₄F₈/O₂ process may be utilized which does not pose any risk of corrosion to aluminum interconnects.

4. The present invention, by using SF₆/C₄F₈/O₂ chemistry also provides a very high selectivity to the resist during the vertical etch step (i.e., 50-60:1) as compared to prior techniques which give a selectivity typically in the range of about 2-3:1. This provides the freedom to control the vertical etch rate independently from the resist etch process steps which control the slope.

5. The prior art often achieves a sloped etch by depositing additional polymeric material to progressively narrow down the trench opening. This results in the reaction chamber becoming very dirty and also requires frequent cleaning of the chamber. The method according to the present invention does not generate any polymeric materials; and, instead, removes the resist slowly.

6. The present invention also provides the advantage of being able to independently control the vertical etch rate and the slope angle by appropriately adjusting the cycle time in the process. Such independent control is not present in the prior art.

7. In the prior art, it is often necessary to use a dielectric mask layer such as oxide or nitride which needs to be deposited and patterned before starting the sloped trench etch process. This results in extra processing steps being necessary. In the method according to the present invention, however, only resist need be used to etch the silicon trenches. This greatly reduces the processing steps and the overall processing cost.

While what has been described herein constitutes presently preferred embodiments of the invention, it should be recognized that the invention can be varied in numerous ways. Accordingly, it should be understood that the present invention should be limited only insofar as is required by the scope of the following claims.

What is claimed:

1. A method for etching a tapered trench in a layer of material, said layer of material having a mask adjacent a surface thereof which has an opening therein defining a location on the layer of material at which the trench is to be formed, said method comprising:
a. performing a vertical etch process step on said layer of material;
b. enlarging the opening in said mask; and
c. repeating steps a and b above in an alternating manner until a trench has been etched to a desired depth.

2. The method according to claim 1, wherein said mask comprises a resist layer, and wherein said enlarging step comprises performing a resist etch process step to enlarge the opening in said resist layer.

3. The method according to claim 2, wherein the resist layer is tapered around a periphery of said opening to facilitate the resist etch process step.

4. The method according to claim 2, wherein said vertical etch process steps and said resist etch process steps are performed in a multi step process.

5. The method according to claim 2, wherein said vertical etch process steps and said resist etch process steps are performed in a pulsed etch process.

6. The method according to claim 1, wherein said trench has a depth of from about 10 um to about 100 um.

7. The method according to claim 6, wherein said trench has sidewalls tapered at a slope of from about 45 degrees to about 80 degrees.

8. The method according to claim 1, wherein said layer of material comprises a semiconductor substrate.

9. The method according to claim 8, wherein said semiconductor substrate comprises a silicon substrate.

10. The method according to claim 1, and further including the step of performing a metal deposition step in said trench when said trench has been etched to a desired depth.

11. The method according to claim 1, wherein said method is incorporated into a process for fabricating a MEMS device.

12. The method according to claim 1, wherein said method is incorporated in a process for fabricating a high power RF device including a LDMOS and a VDMOS device.

13. The method according to claim 1, wherein said method is incorporated in a process for fabricating a Z-axis accelerometer.

14. The method according to claim 1, including the steps of independently controlling one or more of pressure, power, gas flows and time duration during the vertical etch process steps.

15. A method for etching a tapered trench extending into a substrate from a surface thereof, said method comprising:
a. providing a mask adjacent said surface, said mask having an opening defining a location on said substrate at which said trench is to be etched;
b. performing a first vertical etch process step to form a first trench portion at said location;
c. performing a first opening enlarging step for enlarging the opening in said mask;
d. performing a second vertical etch process step to form a second trench portion;
e. performing a second opening enlarging step for further enlarging the opening in said mask; and
f. continuing to perform vertical etch process steps and opening enlarging process steps in an alternating manner until said trench is of a desired depth.

16. The method according to claim 15, wherein said mask comprises a resist layer, and wherein said opening enlarging steps comprise performing resist etch process steps to enlarge the opening in said resist layer.

17. The method according to claim 16, and further including the step of tapering said resist layer around a periphery of said opening prior to performing the first vertical etch process step to facilitate performing the resist etch process steps.

18. The method according to claim 15, wherein said trench has a depth of from about 10 um or less to about 100 um or more.

19. The method according to claim 18, wherein sidewalls of said trench have a slope of from about 45 degrees to about 80 degrees.

20. An apparatus for etching a tapered trench in a layer of material, said layer of material having a mask adjacent a surface thereof having an opening defining a location on the layer of material at which the trench is to be formed, said apparatus comprising:
an etching tool for performing vertical etch process steps on said layer of material; and
an opening enlarging tool for performing steps of enlarging said opening in said mask, said etching tool and said opening enlarging tool operating in an alternating manner to form a trench of a desired depth in said layer of material.

21. The apparatus according to claim 20, wherein said mask comprises a resist layer, and wherein said mask opening enlarging tool comprises a tool for performing resist etch process steps on said resist layer.

22. The apparatus according to claim 21, wherein said resist layer is tapered around the periphery of said opening to facilitate performing of the resist etch process steps.

23. The apparatus according to claim 21, wherein said vertical etch process tool and said resist etch process tool are incorporated in a tool that operates in a pulsed manner.

24. The apparatus according to claim 21, wherein said vertical etch process tool and said resist etch process tool are incorporated in a tool that operates in a multi step manner.
